(19) United States
(12) Patent Application Publication
(10) Pub. No.: US 2014/0311542 A1
(43) Pub. Date: Oct. 23, 2014

(54) THERMOELECTRIC CONVERSION ELEMENT

(71) Applicant: KABUSHIKI KAISHA TOSHIBA, MINATO-KU (JP)

(72) Inventors: HIROMI YUASA, KAWASAKI-SHI (JP); YUUZO KAMIGUCHI, YOKOHAMA-SHI (JP)

(73) Assignee: KABUSHIKI KAISHA TOSHIBA, MINATO-KU (JP)

(21) Appl. No.: 14/198,794

(22) Filed: Mar. 6, 2014

(30) Foreign Application Priority Data
Apr. 22, 2013 (JP) 2013-089414

(51) Int. Cl. H01L 37/00

(52) U.S. Cl. CPC H01L 37/00
USPC 136/205

(57) ABSTRACT

A thermoelectric conversion element includes a substrate, a non-magnetic metal layer, an insulated ferromagnetic layer, and a metallic ferromagnetic layer. The insulated ferromagnetic layer is provided between the substrate and the non-magnetic metal layer. Magnetization of the insulated ferromagnetic layer is fixed in one direction. The metallic ferromagnetic layer is provided between the insulated ferromagnetic layer and the non-magnetic metal layer.

### CROSS-REFERENCE TO RELATED APPLICATION(S)

The present disclosure claims priority to Japanese Patent Application No. 2013-89414, filed on Apr. 22, 2013, which is incorporated herein by reference in its entirety.

### FIELD

Embodiments described herein relates generally to a thermoelectric conversion element.

### BACKGROUND

As one of the thermoelectric conversion elements, one that uses a spin Seebeck effect is known. However, the thermoelectric conversion element using the spin Seebeck effect has a low generating efficiency.

### BRIEF DESCRIPTION OF THE DRAWINGS

FIG. 1 is a diagram for showing a thermoelectric conversion element according to an embodiment of the present invention;

FIG. 2 is a diagram for explaining the embodiment;

FIG. 3 is a diagram for explaining the embodiment;

FIG. 4 is a diagram for explaining the embodiment;

FIG. 5A is a diagram for explaining the embodiment;

FIG. 5B is a diagram for explaining the embodiment;

FIG. 6 is a diagram for explaining the embodiment;

FIG. 7 is a diagram for explaining the embodiment;

FIG. 8 is a diagram for explaining the embodiment;

FIG. 9 is a diagram for explaining the embodiment;

FIG. 10 is a diagram for explaining the embodiment; and

FIG. 11 is a diagram for explaining the embodiment.

### DETAILED DESCRIPTION

Hereinafter, with reference to the accompanying drawings, embodiments of the present invention will be described. What is given the same reference numeral indicates the same component. It is noted that the drawings are schematic or conceptual and that a relationship between a thickness and a width of each portion and a ratio coefficient of sizes between the portions are not necessarily the same as those of actual things. Moreover, even when the same portion is shown, there is also a case where it is shown with different sizes and ratio coefficients depending on the drawings.

### EXAMPLES

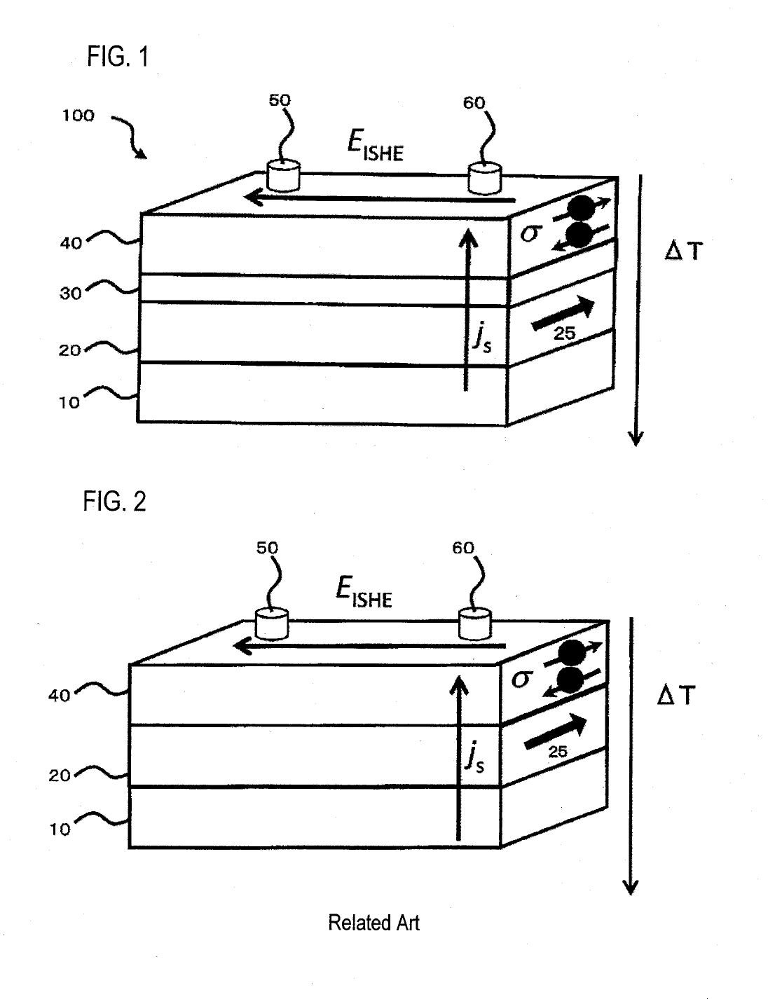

FIG. 1 is a diagram for showing a thermoelectric conversion element 100. The thermoelectric conversion element 100 is configured such that an insulated ferromagnetic layer 20, a metallic ferromagnetic layer 30, and a non-magnetic metal layer 40 are provided in this order on a substrate 10. These may be defined as a laminated body. Furthermore, terminals 50, 60 are provided on the non-magnetic metal layer 40.

An operation principle of the thermoelectric conversion element 100 will be explained. The thermoelectric conversion element 100 can generate electricity by using the spin Seebeck effect.

If a temperature gradient ΔT is applied to the insulated ferromagnetic layer 20 and the metallic ferromagnetic layer 30 between the substrate 10 and the non-magnetic metal layer 40, there occurs a difference between a distribution of up spin electrons and that of down spin electrons in the insulated ferromagnetic layer 20 and the metallic ferromagnetic layer 30. This phenomenon is so called as the spin Seebeck effect, and this occasional difference between the distribution of up spin electrons and the distribution of down spin electrons is so called as a spin pressure.

Here, the non-magnetic metal layer 40 is provided to adjoin the metallic ferromagnetic layer 30. For this reason, the spin pressure that arose in the insulated ferromagnetic layer 20 and the metallic ferromagnetic layer 30 propagates into the non-magnetic metal layer 40 through the metallic ferromagnetic layer 30 as a spin current. The spin current is a flow that arises from the difference between the distribution of up spin electrons and the distribution of down spin electrons, and is not a flow of electric charges. When the spin current propagates into the non-magnetic metal layer 40, an inverse spin Hall effect causes an electric current, which is a flow of electric charges, to flow in a direction perpendicular to the spin current and the magnetization 25 of the insulated ferromagnetic layer 20, which generates an electromotive force. By this, the thermoelectric conversion element 100 generates electricity. It is necessary that the insulated ferromagnetic layer 20, the metallic ferromagnetic layer 30, and the non-magnetic metal layer 40 make contacts with one another. That respective layers adjoin the other layers in this way can make the spin current propagate into the non-magnetic metal layer 40.

FIG. 2 is a diagram showing a configuration of a thermoelectric conversion element according to a related art. The electromotive force generated by the spin Seebeck effect and the inverse spin Hall effect will be explained with reference to FIG. 2. In the thermoelectric conversion element of the related art, the insulated ferromagnetic layer 20 and the non-magnetic metal layer 40 are provided in this order on the substrate 10. Furthermore, the terminals 50, 60 are provided on the non-magnetic metal layer 40. The electromotive force E_{ISHE} generated by the spin Seebeck effect and the inverse spin Hall effect in the non-magnetic metal layer 40 is expressed by the following Formula 1 and Formula 2.

$$\begin{matrix}{E}_{ISHE} = ( {θ}_{SH} ρ ) {j}_{spin} \times σ & ( 1 ) \\ {j}_{spin} = \frac{γ \cdot ℏ \cdot {g}_{r} / A \cdot {k}_{B}}{2 π \cdot {M}_{S} \cdot {V}_{a}} \frac{2 e}{ℏ} Δ T & ( 2 )\end{matrix}$$

Here, E_{ISHE} is an inverse spin Hall effect voltage arising in the non-magnetic metal layer 40, θ_{SH} is a spin Hall angle in the non-magnetic metal layer 40, ρ is an electric resistivity in the non-magnetic metal layer 40, Jₛₚᵢₙ is the spin current that flows from the insulated ferromagnetic layer 20 to the non-magnetic metal layer 40, σ is a spin polarization vector in the non-magnetic metal layer 40, e is an electric charge in the non-magnetic metal layer 40, A is a junction area between the non-magnetic metal layer 40 and the metallic ferromagnetic layer 30 or the insulated ferromagnetic layer 20, γ is a gyromagnetic constant of the insulated ferromagnetic layer 20, gᵣ is an interface mixing resistance between the metallic ferromagnetic layer 30 or the insulated ferromagnetic layer 20 and the non-magnetic metal layer 40, 4πM_{S} is a saturation magnetization of the insulated ferromagnetic layer 20, Vₐ is a magnetic coherence length cubed of the insulated ferromagnetic layer 20, and ΔT is a temperature gradient in a portion between the non-magnetic metal layer 40 and the insulated ferromagnetic layer 20.

The electromotive force E_{ISHE} and the spin current Jₛₚᵢₙ will be explained using Formulae 1 and 2.

Formula 1 shows that as the spin Hall angle θ_{SH} in the non-magnetic metal layer 40 becomes higher, the electromotive force E_{ISHE} increases more. The spin Hall angle θ_{SH} shows a conversion efficiency by which the spin current flowing in the non-magnetic metal layer 40 is converted into the electric current. If a material having a large spin orbit interaction is employed for the non-magnetic metal layer 40, the spin Hall angle θ_{SH} becomes larger.

According to Formula 2, when the interface mixing resistance gᵣ between the insulated ferromagnetic layer 20 and the non-magnetic metal layer 40 becomes larger, the spin current Jₛₚᵢₙ becomes larger. Therefore, in accordance with Formula 1, the electromotive force E_{ISHE} becomes larger. For example, while a value of the interface mixing resistance between Pt and Y₃Fe₅O₁₂ is 10¹⁵ to 10¹⁶ m⁻², a value of the interface mixing resistance between Pt and NiFe is 10¹⁷ to 10¹⁸ m². In view of the value of the interface mixing resistance gᵣ, the interface between Pt and NiFe is more preferable than the interface between Pt and Y₃Fe₅O₁₂. Generally, the interface between the non-magnetic metal layer 40 and the metallic ferromagnetic layer 30 has a higher interface mixing resistance than the interface between the non-magnetic metal layer 40 and the insulated ferromagnetic layer 20. Then, if the metallic ferromagnetic layer 30 is inserted between the non-magnetic metal layer 40 and the insulated ferromagnetic layer 20, a large electromotive force is expectable to the thermoelectric conversion element 100. However, since the metallic ferromagnetic layer 30 has metallicity, an electric current generated in the non-magnetic metal layer 40 leaks to the metallic ferromagnetic layer 30, which loses the electromotive force. In order to deal with this matter, the metallic ferromagnetic layer 30 may have a thickness in a predetermined range. This is also applicable for the case where Pt is replaced with Ta for the non-magnetic metal layer 40.

A flexible substrate is used for the substrate 10 in order to generate electricity with depending on a comparatively large area by making use of every heat generation surface. The substrate 10 is preferable to have flexibility with its Young's modulus being less than or equal to 10. Polyimide, polypropylene, nylon, polyester, parylene, a rubber, a biaxially stretched polyethylene-2,6-naphthalate, or a modified polyamide may be used for the substrate 10.

In the insulated ferromagnetic layer 20, its magnetization is fixed in one direction. The magnetization of the insulated ferromagnetic layer 20 faces in an in-plane direction of the insulated ferromagnetic layer 20. This is because the temperature gradient occurs in a lamination direction of the laminated body that constitutes the thermoelectric conversion element 100, and the magnetization of the insulated ferromagnetic layer 20 must be perpendicular to the temperature gradient. A garnet ferrite (Y₃Fe₅O₁₂), a spinel ferrite, or a hexagonal ferrite may be used for the insulated ferromagnetic layer 20. Since the spin current is generated in the insulated ferromagnetic layer 20, the insulated ferromagnetic layer 20 is also called a spin current generating layer.

NiFe may be used for the metallic ferromagnetic layer 30. If the film thickness of the metallic ferromagnetic layer 30 is too thick, an electric current generated in the non-magnetic metal layer 40 will leak to the metallic ferromagnetic layer 30. For this reason, it is preferable that the film thickness of the metallic ferromagnetic layer 30 is not less than one-atom layer and not more than ten-atom layer. Moreover, since CoFe and CoNi have larger interface mixing resistances with Y₃Fe₅O₁₂, CoFe or CoNi may be used for the metallic ferromagnetic layer 30. Fe, Co, or Ni or arroys containing at least two elements selected from the group consisting of Fe, Co, and Ni may also be used for the metallic ferromagnetic layer 30. Since these materials have a characteristic that the interface mixing resistances gᵣ are large in their interfaces with the non-magnetic metal layer 40, any of them may be used for the metallic ferromagnetic layer 30 like CoFe, CoNi, or NiFe.

Ta and/or W is used for the non-magnetic metal layer 40. In a related art, Pt was used for the non-magnetic metal layer. However, Pt 0.0037 to 0.07 in spin Hall angle. On the other hand, since Ta has 0.12 to 0.15 in spin Hall angle, a generating efficiency improves as compared with Pt. These values of the spin Hall angle can be obtained by an evaluation method of FMR (Ferromagnetic Resonance). Crystal structures of Ta include amorphous crystal structure, cubic crystal structure, and tetragonal crystal structure. With any one of these crystal structures, use of Ta improves the electromotive force than use of Pt. However, Ta having the cubic crystal structure is preferable. This is because the electric resistivity of the cubic Ta is lower than amorphous Ta. Moreover, tetragonal Ta is further preferable. This is because it has a larger spin Hall angle. Tetragonal Ta is called as β-Ta. Similarly, when using W for the non-magnetic metal layer 40, β-W having the tetragonal crystal structure is preferable. Adding at least one element selected from the group consisting of Hf, W, Ir, Pt, Au, Pb, and Bi to the non-magnetic metal layer 40 containing Ta will further raise the electromotive force. Similarly, adding at least one element selected from the group consisting of Hf, Ta, Ir, Pt, Au, Pb, and Bi to the non-magnetic metal layer 40 containing W will further raise the electromotive force. These elements are added to the non-magnetic metal layer 40 by not less than 3 at % and not more than 30 at %. These elements each have a function of increasing a spin orbit interaction in the non-magnetic metal layer 40 and increasing the spin Hall angle θ_{SH}. For this reason, the generating efficiency of the thermoelectric conversion element 100 improves.

Moreover, at least one element selected from the group consisting of Fe, Co, Ni, Mn, and Cr may be added to the non-magnetic metal layer 40 containing Ta or W. These elements are added to the non-magnetic metal layer 40 by not more than 1 at %. These elements may be added thereto together with another element such as Hf, W, Ta, Ir, Pt, Au, Pb, and/or Bi that have been described above. Since these elements are small in quantity, the non-magnetic metal layer 40 still remains non-magnetic as a whole. Since these elements are each localized in the non-magnetic metal layer 40, each of them has a function of increasing the spin orbit interaction and increasing the spin Hall angle θ_{SH}. For this reason, the generating efficiency of the thermoelectric conversion element 100 improves. Since the non-magnetic metal layer 40 detects the spin current, it is also called as a spin current detecting layer.

Here, the generating efficiency is defined by an electric power (W/m²) generated per unit area.

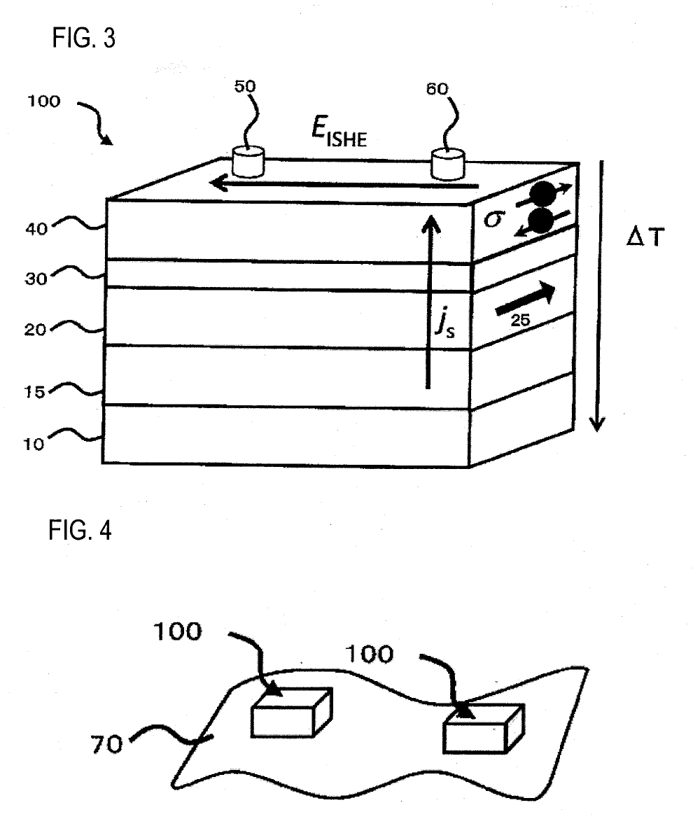

As shown in FIG. 3, an antiferromagnetic layer 15 may be provided between the insulated ferromagnetic layer 20 and the substrate 10. The laminated body of the insulated ferromagnetic layer 20, the metallic ferromagnetic layer 30, and the non-magnetic metal layer 40 in which the antiferromagnetic layer 15 is included may be defined as a laminated body. Since the use of the antiferromagnetic layer 15 enables the magnetization of the insulated ferromagnetic layer 20 to be faced to one direction, the electromotive force that occurs in the non-magnetic metal layer 40 can be stabilized. This is because since a direction of an electric current generated from the inverse spin Hall effect, occurring in the non-magnetic metal layer 40, faces a direction of an outer product of (i) a direction of the spin current flowing toward the non-magnetic metal layer 40 from the insulated ferromagnetic layer 20 and the magnetization direction of the insulated ferromagnetic layer 20, in order to arrange directions of the electric current flowing in the non-magnetic metal layer 40, it is required to fix the magnetization direction of the insulated ferromagnetic layer 20 in one direction.

IrMn or Fe₂O₃ may be used for the antiferromagnetic layer 15. Since the use of the antiferromagnetic layer 15 makes an interchange coupling between the antiferromagnetic layer 15 and the insulated ferromagnetic layer 20, the magnetization of the insulated ferromagnetic layer 20 can be fixed in one direction.

### Example 1

Ni—Zn ferrite (having 100 nm in thickness and corresponding to the insulated ferromagnetic layer 20) and Ta (having 10 nm in thickness and corresponding to the non-magnetic metal layer 40) were laminated on polyimide (corresponding to the substrate 10), and two terminals made of Cu were provided on Ta to fabricate a thermoelectric conversion element. The element had a rectangle shape and 5 mm in width. A distance between the terminals where the electromotive force occurs was 3 cm. Furthermore, a surface of polyimide was set up on skin (about 34° C.), and the electromotive force occurring between the two terminals was measured. The electromotive force at this time was 10 μV.

### Example 1-2

Ni—Zn ferrite (having 100 nm in thickness and corresponding to the insulated ferromagnetic layer 20) and W (having 10 nm in thickness and corresponding to the non-magnetic metal layer 40) were laminated on polyimide (corresponding to the substrate 10), and two terminals made of Cu were provided on W to fabricate a thermoelectric conversion element. The element had a rectangle shape and 5 mm in width. A distance between the terminals where the electromotive force occurs was 3 cm. Furthermore, the surface of polyimide was set up on the skin (about 34° C.), and the electromotive force occurring between the two terminals was measured. The electromotive force at this time was 20 μV.

### Example 2

Ni—Zn ferrite (having 100 nm in thickness and corresponding to the insulated ferromagnetic layer 20), NiFe (having 0.2 nm in thickness and corresponding to the metallic ferromagnetic layer 30), and Ta (having 10 nm in thickness and corresponding to the non-magnetic metal layer 40) were laminated on polyimide (corresponding to the substrate 10), and two terminals made of Cu were provided on Ta to fabricate the thermoelectric conversion element 100. Furthermore, the surface of polyimide was set on the skin (about 34° C.), and a current flowing between the two terminals was measured. The electromotive force at this time was 100 μV.

### Example 2-2

Ni—Zn ferrite (having 100 nm in thickness and corresponding to the insulated ferromagnetic layer 20), NiFe (having 2 nm in thickness and corresponding to the metallic ferromagnetic layer 30), and Ta (having 10 nm in thickness and corresponding to the non-magnetic metal layer 40) were laminated on polyimide (corresponding to the substrate 10), and two terminals made of Cu were provided on Ta to fabricate the thermoelectric conversion element 100. Furthermore, the surface of polyimide was set up on the skin (34° C.), and a current flowing between the two terminals was measured. The electromotive force at this time was 50 μV.

### Comparative Example 1

Ni—Zn ferrite (having 100 nm in thickness and corresponding to the insulated ferromagnetic layer 20) and Pt (having 10 nm in thickness; corresponding to the non-magnetic metal layer 40) were laminated on polyimide (corresponding to the substrate 10), and two terminals made of Cu were provided on Pt to fabricate a thermoelectric conversion element. Furthermore, the surface of polyimide was set up on the skin (about 34° C.), and the current flowing between the two terminals was measured. The electromotive force at this time was 1 μV.

### Comparative Example 2

Ni—Zn ferrite (having 100 nm in thickness and corresponding to the insulated ferromagnetic layer 20), NiFe (having 10 nm in thickness and corresponding to the metallic ferromagnetic layer 30), and Ta (having 10 nm in thickness and corresponding to the non-magnetic metal layer 40) were laminated on polyimide (corresponding to the substrate 10), and two terminals made of Cu were provided on Ta to fabricate the thermoelectric conversion element 100. Furthermore, the surface of polyimide was set up on the skin (about 34° C.), and a current flowing between the two terminals was measured. The electromotive force at this time was 0.1 μV.

From the example 1, the example 1-2, and the comparative example 1, it can be seen that in order to obtain a large electromotive force, it is advantageous to use Ta and/or W for the non-magnetic metal layer 40. Moreover, from the example 2 and the comparative example 2, it can be seen that in order to obtain the large electromotive force, it is advantageous to further insert the rather thin metallic ferromagnetic layer 30 between the non-magnetic metal layer 40 and the insulated ferromagnetic layer 20. This is because inserting NiFe between Ta and Ni—Zn ferrite contributes to improvement in the interface mixing resistance between NiFe and Ni—Zn ferrite. Moreover, since the film thickness of the metallic ferromagnetic layer 30 is thin, it is hard for the current flowing in the non-magnetic metal layer 40 to leak to the metallic ferromagnetic layer 30. From comparisons among the example 2, the example 2-2, and the comparative example 2, it is preferable that the film thickness of the metallic ferromagnetic layer 30 is not less than one-atom layer and not more than 10-atom layer.

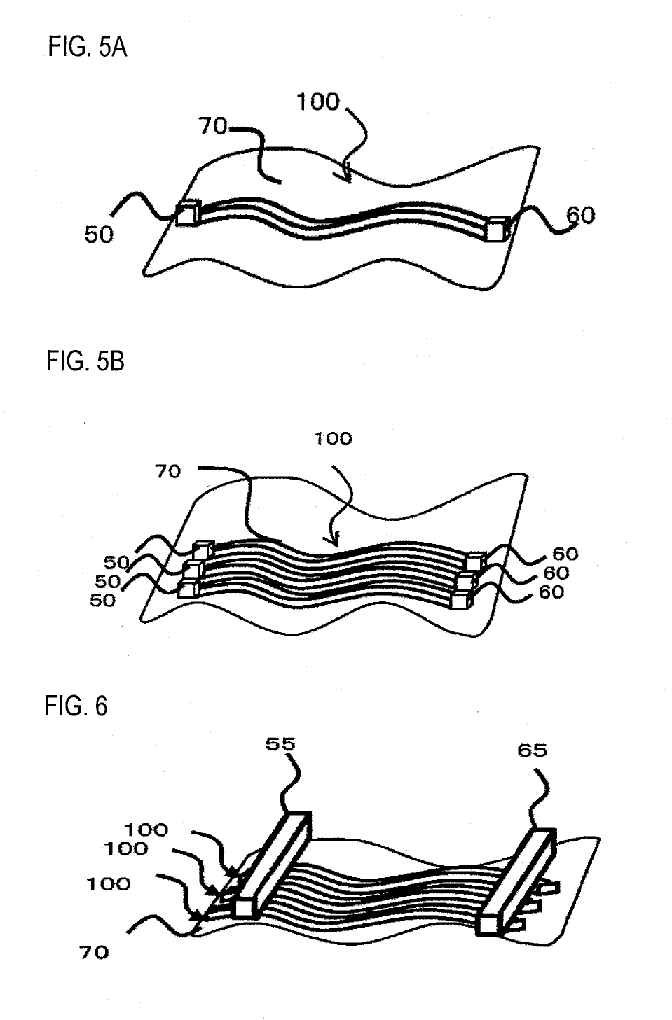

As shown in FIG. 4, a couple of thermoelectric conversion elements 100 may be provided on a flexible sheet 70. Moreover, as shown in FIG. 5A, if the thermoelectric conversion element 100 is of a elongated fine wire type, the electromotive force can be raised. The thickness of the fine wire is not less than 1 μm and not more than 1 cm. This is because if it is formed into the fine wire type, its contact area with the flexible sheet 70 becomes larger. At this time, the terminals 50, 60 are provided on both ends of the laminated body that constitutes the thermoelectric conversion element 100. Moreover, as shown in FIG. 5B, if the fine wire type thermoelectric conversion elements are aligned to increase a coverage of the thermoelectric conversion element 100 on the flexible substrate, the generating efficiency will increase. As shown in FIG. 6, when multiple fine wire type thermoelectric conversion elements 100 are formed on the flexible sheet 70, electrodes 55, 65 are electrically connected to both ends of the fine wire type thermoelectric conversion elements 100 instead of the terminals 50, 60. For a material of the electrodes 55, 65, the material of the terminals 50, 60 may be used. When the electromotive force is increased with depending on the fine wire type shape, the current will decrease, but the electric power that is generated in the thermoelectric conversion element remains the same. However, technical meaning can be found out in increasing the voltage in spite of the electric power remaining the same as will be explained below.

When the voltage of the power generation element is too high or too low to a load circuit, the voltage needs to be stepped down or boosted by a subsequent regulator circuit. In that case, the electric power falls to about 80%, and about 20% becomes energy loss. If the voltages of the load circuit and the power generation element are relatively the same level, the necessity for adjustment will be eliminated so that the loss can be reduced. Even when adjustment is required, the smaller the amount of adjustment is, the less energy loss can be made. In view of this, since the amount of electricity generated by the thermoelectric conversion element is generally considered small to the load circuit, a booster circuit was needed. On the other hand, if the thermoelectric conversion element(s) are formed into the fine wire type in advance to have a higher voltage, adjustment will become unnecessary or something very small. Therefore, it will become possible to eliminate or minimize the energy loss. As described above, it has a merit that the voltage can be adjusted to the same electric power according to a design of the circuit with the same electric power. The fine wire type can be formed by patterning with a mask, photolithography, or printing.

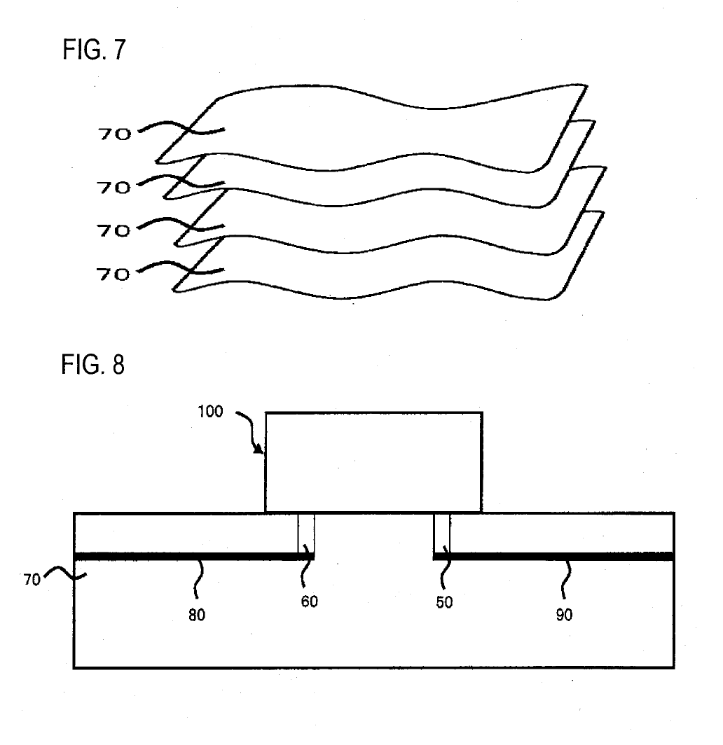

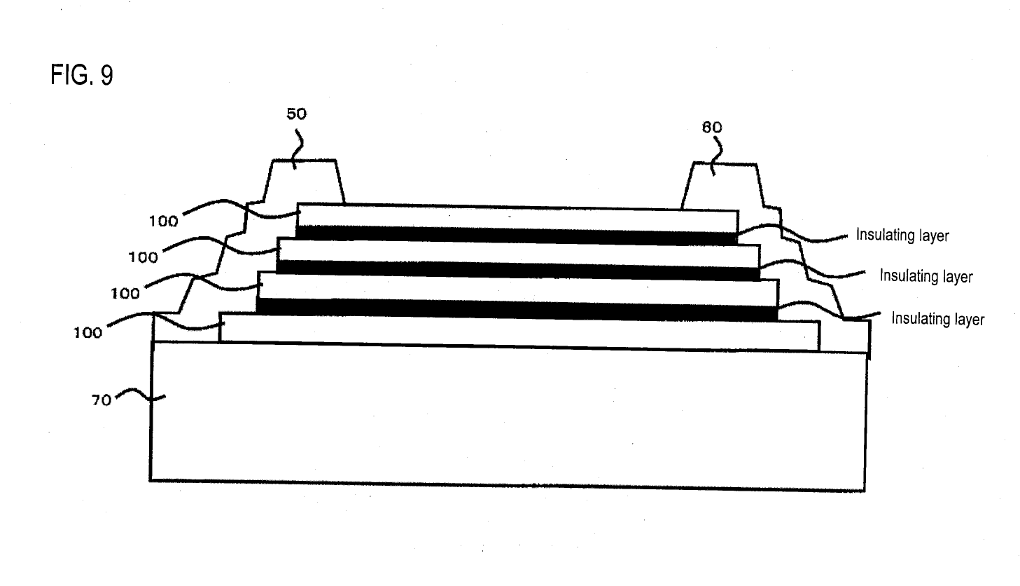

Moreover, as shown in FIG. 7, multiple flexible sheets may be stacked and used, on each of which the thermoelectric conversion element 100 is provided. At this time, wiring is stringed around in the flexible sheet 70, and electric power is obtained therefrom. For example, as shown in FIG. 8, the terminals 50, 60 of the thermoelectric conversion element 100 may be embedded in the flexible sheet 70, and wiring 90, 80 may be taken out from the terminals 50, 60, respectively. Furthermore, as shown in FIG. 9, if the multiple thermoelectric conversion elements 100 are laminated through insulating layers, and the higher the stage in which the thermoelectric conversion element is placed is, the smaller the area of that thermoelectric conversion element in an in-plane direction is made, the thermoelectric conversion elements 100 can be laminated upward from the bottom and the terminals 50, 60 can be formed by collective film formation. This is formed using technologies of film formation of sputtering etc. with a mask, photolithography, or printing. Such a configuration in which multiple thermoelectric conversion elements are stacked can use a temperature difference effectively. For example, a temperature difference between the body surface of a human body and the open air are often more than or equal to 5° C. However, since the insulated ferromagnetic layer 20 is thin, a temperature difference between a top surface and an under surface of the insulated ferromagnetic layer 20/metallic ferromagnetic layer 30 becomes often less than or equal to 0.1° C. If the temperature difference between the top surface and the under surface is 0.1° C., by using a configuration in which several sheets of the flexible sheets 70 (in FIG. 7, four sheets are shown) on each of which the thermoelectric conversion element 100 as shown in FIG. 7 is provided are laminated, a temperature difference as much as 0.4° C. can be used effectively because the each thermoelectric conversion element 100 obtains the temperature difference of 0.1° C., respectively. That is, even with the same area, the generated electric power equal to four times can be obtained and the generating efficiency that is the amount of electricity generated per unit area becomes four times. Thus, by laminating the thermoelectric conversion elements, the temperature difference between the body surface of the human body and the open air can be used effectively to increase the generating efficiency.

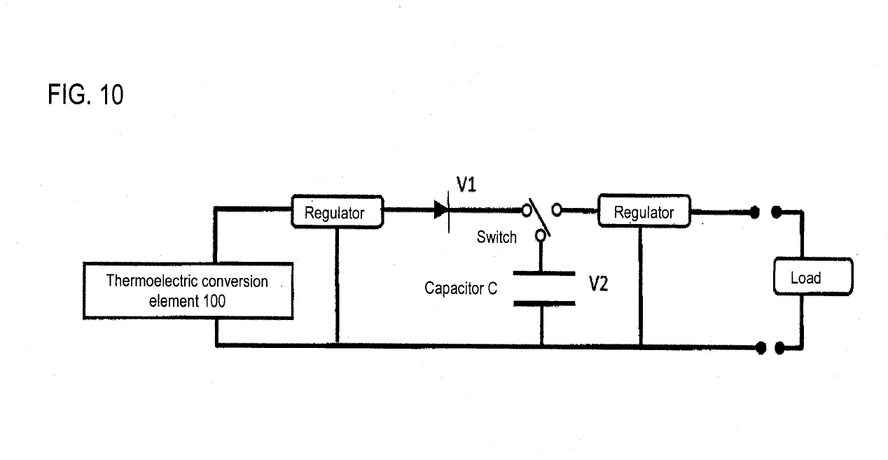

FIG. 10 is a diagram showing one example of a circuit configuration using the thermoelectric conversion element 100. The electric power generated by the thermoelectric conversion element 100 is boosted or stepped down by a regulator (DC-DC converter) according to a capacitor and is stored in the capacitor. Here, V1 denotes the electromotive force generated by thermoelectric conversion element 100, and V2 denotes the voltage of the charged capacitor C. When the load operates, either the capacitor or the thermoelectric conversion element 100 having a higher voltage supplies electric power to the load. Moreover, the voltage is adjusted by a regulator according to the driving voltage of the load. Thus, the stable electric power can be supplied to the load.

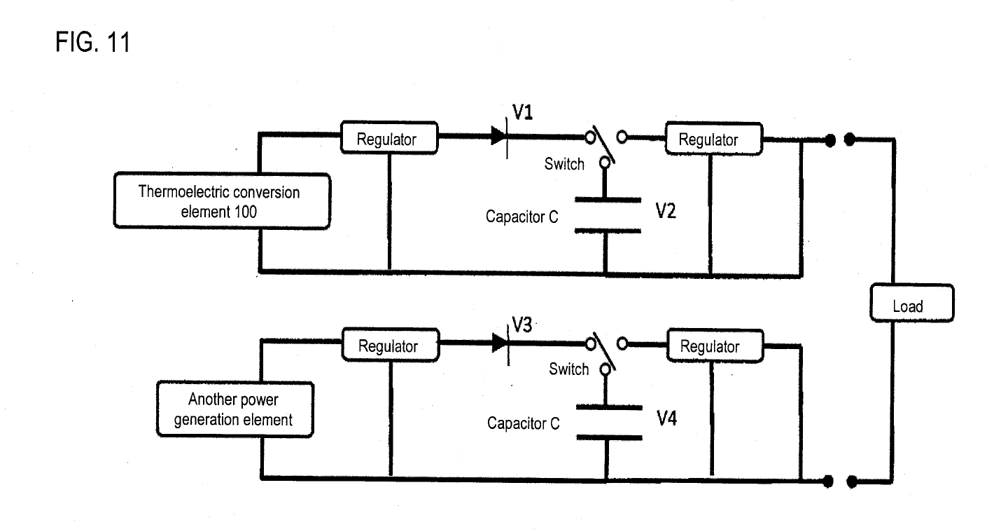

As shown in FIG. 11, the circuit may be configured such that another power generation element is further connected to the load, and multiple power generation elements each of which has a different power generation system may used together. Here, V3 denotes the electromotive force generated by another power generation element, and V4 denotes the voltage of the charged capacitor. This is called a hybrid type. For example, in a place upon which the sun like daytime is blazing down, power generation by a solar panel is performed in the other power generation element, and power generation by the thermoelectric conversion element 100 is performed at night using heat sources, such as a body temperature and terrestrial heat. In FIG. 11, the circuit is configured so that the thermoelectric conversion element 100 may be connected in parallel with the other power generation element, and the electric power may be supplied from the element having a higher voltage to the load. This enables further stabilized electric power to be supplied to the load.

Examples of the load include, for example, a sensor, a circuit, an oscillator, and a position monitor. For example, when this circuit is used for the oscillator for emergency contact, it has a merit that there is no risk of power supply loss. At this time, the circuit generates electricity using the body temperature of the human body. Since there is no risk of power supply loss also when being used for a position monitor, the circuit may be used for a case where there is a need to watch a child, etc.

Although the exemplary embodiments of the present invention have been described above, these embodiments are presented just as examples, and it is not intended to limit a range of the invention. These new embodiments may be carried out with other various modes, and a variety of omissions, replacements, and modifications may be made within a range that does not deviate from a gist of the invention. These embodiments and their modifications are included not only in the range and the gist of the invention but are also included in the invention described in the scope of the claim of the invention and its equivalent range.

What is claimed is:

1. A thermoelectric conversion element comprising:
a substrate;
a non-magnetic metal layer;
an insulated ferromagnetic layer that is provided between the substrate and the non-magnetic metal layer, magnetization of the insulated ferromagnetic layer being fixed in one direction; and
a metallic ferromagnetic layer provided between the insulated ferromagnetic layer and the non-magnetic metal layer.

2. The element according to claim 1, wherein the non-magnetic metal layer includes Ta.

3. The element according to claim 1, wherein the non-magnetic metal layer includes β-Ta or β-W.

4. The element according to claim 2, wherein the non-magnetic metal layer further includes at least one element selected from the group consisting of Hf, W, Ta, Ir, Pt, Au, Pb, and Bi.

5. The element according to claim 2, wherein the non-magnetic metal layer further includes at least one element selected from the group consisting of Fe, Co, Ni, Mn, and Cr.

6. The element according to claim 1, wherein the non-magnetic metal layer and the metallic ferromagnetic layer adjoin each other.

7. The element according to claim 1, further comprising:
a first terminal and a second terminal that are provided separately on the non-magnetic metal layer.

8. The element according to claim 7, wherein when a temperature gradient occurs between the substrate and the non-magnetic metal layer, an electromotive force occurs between the first terminal and the second terminal on the non-magnetic metal layer.

9. The element according to claim 1, wherein the metallic ferromagnetic layer includes at least one element selected from the group consisting of Fe, Co, and Ni.

10. The element according to claim 1, wherein the insulated ferromagnetic layer includes a garnet ferrite, a spinel ferrite, or a hexagonal ferrite.

11. The element according to claim 1, further comprising:
an antiferromagnetic layer between the substrate and the insulated ferromagnetic layer.

12. The element according to claim 1, wherein a Young's modulus of the substrate is less than or equal to 10.

13. The element according to claim 1, wherein the substrate includes polyimide, polypropylene, nylon, polyester, parylene, a rubber, a biaxially stretched polyethylene-2, 6-naphthalate, or a modified polyamide.

14. The element according to claim 1, wherein a film thickness of the metallic ferromagnetic layer is not less than one-atom layer and not more than ten-atom layer.
